(19) United States
(12) Patent Application Publication
(10) Pub. No.: US 2025/0175034 A1
(43) Pub. Date: May 29, 2025

(54) RESONATOR STRUCTURE AND WIRELESS POWER TRANSFER DEVICE COMPRISING SAME

(71) Applicant: Samsung Electronics Co., Ltd., Suwon-si, (KR)

(72) Inventors: Jaehyun PARK, Suwon-si (KR); Beomwoo GU, Suwon-si (KR); Minbeom KO, Suwon-si (KR); Joonhong KIM, Suwon-si (KR); Jaeseok PARK, Suwon-si (KR); Sungku YEO, Suwon-si (KR)

(21) Appl. No.: 19/034,064

(22) Filed: Jan. 22, 2025

Related U.S. Application Data
(63) Continuation of application No. PCT/KR2023/016387, filed on Oct. 20, 2023.

(30) Foreign Application Priority Data
Nov. 11, 2022 (KR) 10-2022-0150859

(51) Int. Cl. H02J 50/12; H01F 7/06; H01R 13/62; H02J 50/00; H02J 50/90

(52) U.S. Cl. CPC H02J 50/12; H01F 7/06; H01R 13/62; H02J 50/005; H02J 50/90

(57) ABSTRACT

A wireless power transfer device is provided. The wireless power transfer device includes a resonator including at least one coil and at least one capacitor, a fixed magnetic body coupled to the at least one coil, a moving magnetic body disposed to be slidable in a first direction on the at least one coil, a feeding coil at least partially coupled to the movable magnetic body and configured to slide together with the movable magnetic body, and a movement module disposed at the at least one coil and is configured to provide a driving force for sliding the movable magnetic body in the first direction.

### CROSS-REFERENCE TO RELATED APPLICATION(S)

This application is a continuation application, claiming priority under 35 U.S.C. § 365 (c), of an International application No. PCT/KR2023/016387, filed on Oct. 20, 2023, which is based on and claims the benefit of a Korean patent application number 10-2022-0150859, filed on Nov. 11, 2022, in the Korean Intellectual Property Office, the disclosure of which is incorporated by reference herein in its entirety.

### BACKGROUND

### 1. Field

The disclosure relates to a wireless power transmission device. More particularly, the disclosure relates to a resonator structure and a wireless power transmission device including the same.

### 2. Description of Related Art

Wireless charging technology refers to a technology of automatically charging a battery of a portable phone by simply placing the portable phone on a wireless power transmission device (e.g., a charging pad) without connecting the portable phone to a separate charging connector. This wireless charging technology may enhance waterproofing due to no need for a connector for supplying power to an electronic product and increase the portability of an electronic device due to no need for a wired charger.

Along with the development of the wireless charging technology, methods of supplying power to various electronic devices (e.g., wireless power reception devices) and charging them with the power by a single electronic device (e.g., a wireless power transmission device) are under study. The wireless charging technology includes an electromagnetic induction scheme, a resonance scheme using resonance, and a radio frequency (RF)/microwave radiation scheme in which electrical energy is converted into microwaves and transferred.

Recently, the wireless charging technology based on electromagnetic induction or resonance has been used mainly in electronic devices such as smartphones. When a resonator (a power transmitting unit (PTU)) (e.g., a wireless power transmission device) and a power receiving unit (PRU) (e.g., a wireless power reception device) come into contact with each other or approach each other within a specific distance, a battery of the PRU may be charged based on electromagnetic induction or electromagnetic resonance between a transmission coil of the resonator and a reception coil of the PRU.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a resonator structure and a wireless power transmission device including the same.

Additional aspects will be set forth in part in the description which follows and, in part, will be apparent from the description, or may be learned by practice of the presented embodiments.

In accordance with an aspect of the disclosure, a wireless power transmission device is provided. The wireless power transmission device includes a resonator including at least one coil and at least one capacitor, a fixed magnetic body coupled to the at least one coil, a movable magnetic body disposed to be slidable in a first direction on the at least one coil, a feeding coil at least partially coupled to the movable magnetic body and configured to slide together with the movable magnetic body, and a movement module disposed at the at least one coil and configured to provide a driving force for sliding the movable magnetic body in the first direction.

In accordance with another aspect of the disclosure, a wireless power transmission device is provided. The wireless power transmission device includes a resonator including at least one coil and at least one capacitor, a fixed magnetic body coupled to the at least one coil, a movable magnetic body disposed to be movable on the at least one coil, a feeding coil at least partially coupled to the movable magnetic body and configured to move together with the movable magnetic body, and a movement module disposed at the at least one coil and configured to provide a driving force for moving the movable magnetic body.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a wireless power transmission system according to an embodiment of the disclosure;

FIG. 2 is a perspective view illustrating a wireless power transmission device and at least one electronic device according to an embodiment of the disclosure;

FIGS. 3A and 3B are plan views illustrating a wireless power transmission device according to various embodiments of the disclosure;

FIG. 4 is a perspective view illustrating a wireless power transmission device according to an embodiment of the disclosure;

FIG. 5A is a cross-sectional view illustrating an automatic matching module according to an embodiment of the disclosure;

FIG. 5B is a cross-sectional view illustrating an automatic matching module according to an embodiment of the disclosure;

FIG. 6A is a Smith chart illustrating input impedances of a resonator according to distances between a wireless power transmission device and an electronic device according to an embodiment of the disclosure;

FIG. 6B is a Smith chart illustrating input impedances of a resonator according to distances between a wireless power transmission device and an electronic device according to an embodiment of the disclosure;

FIG. 6C is a Smith chart illustrating input impedances of a resonator according to distances between a wireless power transmission device and an electronic device according to an embodiment of the disclosure;

FIG. 7A illustrates a wireless power transmission device and an electronic device according to an embodiment of the disclosure;

FIG. 7B is a detailed block diagram illustrating a power transmission circuit and a power reception circuit according to an embodiment of the disclosure;

FIGS. 8A and 8B are cross-sectional views illustrating an automatic matching module according to various embodiments of the disclosure;

FIGS. 9A and 9B are perspective views illustrating a wireless power transmission device according to various embodiments of the disclosure;

FIG. 9C is a cross-sectional view illustrating an automatic matching module according to an embodiment of the disclosure;

FIGS. 10A and 10B are plan views illustrating a wireless power transmission device according to various embodiments of the disclosure;

FIG. 10C is a perspective view illustrating a wireless power transmission device according to an embodiment of the disclosure;

FIG. 11 is a perspective view illustrating at least one coil and a movable magnetic body according to an embodiment of the disclosure;

FIGS. 12A and 12B are cross-sectional views illustrating an automatic matching module according to various embodiments of the disclosure; and

FIGS. 13A and 13B are perspective views illustrating a wireless power transmission device according to various embodiments of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the disclosure, reference numerals in each operation are used for convenience of description, and do not describe the order of operations. Each operation may be performed in a different order from the illustrated one, unless a specific order is clearly stated in the context.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

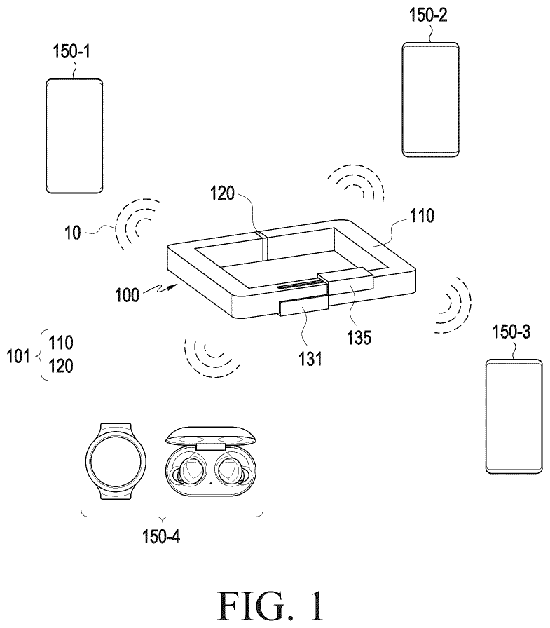

FIG. 1 is a diagram illustrating a wireless power transmission system according to an embodiment of the disclosure.

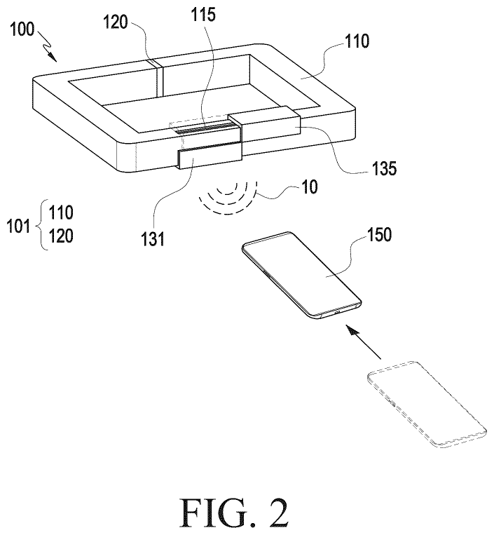

The embodiment of FIG. 1 may be combined with the embodiments of FIGS. 2, 3A, 3B, 4, 5A, 5B, 6A to 6C, 7A, 7B, 8A, 8B, 9A to 9C, 10A to 10C, 11, 12A, 12B, 13A, and 13B.

Referring to FIG. 1, a wireless power transmission device 100 according to an embodiment may wirelessly transmit power 10 to a wireless power reception device 150 (hereinafter, referred to as an ‘electronic device 150’). The wireless power transmission device 100 may transmit the power 10 to the electronic device 150 according to various charging schemes. For example, the wireless power transmission device 100 may transmit the power 10 according to an induction scheme. When the wireless power transmission device 100 uses the induction scheme, the wireless power transmission device 100 may include, for example, a power source, a DC-AC conversion circuit, an amplifier circuit, an impedance matching circuit, at least one capacitor 120, at least one coil 110, a communication modulation/demodulation circuit, and so on. The at least one capacitor 120 may form a resonant circuit 101 (or a resonator 101) together with the at least one coil 110. The wireless power transmission device 100 may be implemented in the manner defined in the Wireless Power Consortium (WPC) standard (or the Qi standard). In addition, for example, the wireless power transmission device 100 may transmit the power 10 according to a resonance scheme. In the resonance scheme, the wireless power transmission device 100 may include, for example, a power source, a DC-AC conversion circuit, an amplifier circuit, an impedance matching circuit, the at least one capacitor 120, the at least one coil 110, and an out-of-band or short-range communication module (e.g., a Bluetooth low energy (BLE) short-range communication module). The at least one capacitor 120 and the at least one coil 110 may form the resonant circuit 101 (or the resonator 101). The wireless power transmission device 100 may be implemented in the manner defined in the Alliance for Wireless Power (A4WP) standard (or the Air Fuel Alliance (AFA) standard). The wireless power transmission device 100 may include at least one transmitting coil 110 capable of generating a time-varying magnetic field whose magnitude changes over time, when an AC current flows according to the resonance scheme or the induction scheme. The process of generating a magnetic field by the wireless power transmission device 100 may be expressed as output or wireless transmission of the power 10 from the wireless power transmission device 100. In addition, the electronic device 150 may include a coil in which an induced electromotive force is generated by a magnetic field whose magnitude changes over time formed in the surroundings. The process of generating an induced electromotive force through the coil by the electronic device 150 may be expressed as input of the power 10 to or wireless reception of the power 10 at the electronic device 150.

The wireless power transmission device 100 according to an embodiment of the disclosure may communicate with the electronic device 150. For example, the wireless power transmission device 100 may communicate with the electronic device 150 according to an in-band scheme. The wireless power transmission device 100 or the electronic device 150 may change the load (or load impedance) of data to be transmitted, for example, according to on/off keying modulation. The wireless power transmission device 100 or the electronic device 150 may determine data transmitted from the counterpart device by measuring a load change (or a load impedance change) based on a change in the magnitude of the current, voltage, or power of the coil. In addition, for example, the wireless power transmission device 100 may perform communication with the electronic device 150 according to an out-of-band scheme. The wireless power transmission device 100 or the electronic device 150 may transmit and receive data using a short-range communication module (e.g., a BLE communication module) provided separately from the coil or a patch antenna. The frequency band of the wireless power and the band of the short-range communication module are separated from each other. For example, in the AirFuel standard, the frequency band of wireless power is 6.78 MHz, and the frequency band of the short-range communication module is 2.4 GHZ.

In the disclosure, when it is said that the wireless power transmission device 100 or the electronic device 150 performs a specific operation, it may mean that various hardware included in the wireless power transmission device 100 or the electronic device 150, such as a processor, a coil, or a patch antenna, performs the specific operation. Alternatively, when it is said that the wireless power transmission device 100 or the electronic device 150 performs a specific operation, it may mean that the processor controls other hardware to perform the specific operation. Alternatively, when it is said that the wireless power transmission device 100 or the electronic device 150 performs a specific operation, it may mean that as an instruction for performing the specific operation stored in a storage circuit (e.g., memory) of the wireless power transmission device 100 or the electronic device 150 is executed, the instruction enables the processor or other hardware to perform the specific operation.

Referring to FIG. 1, the wireless power transmission device 100 may wirelessly establish electrical connections with a plurality of electronic devices 150-1, 150-2, . . . , 150-n. The plurality of electronic devices may include, for example, at least one of portable communication devices 150-1, 150-2, and 150-3 (e.g., smartphones), a wearable device 150-4 (e.g., a watch, wireless earphones, an AR/VR device), a portable multimedia device (e.g., a touch pad or a laptop), a PDA, a PMP, a camera, a portable medical device, or a home appliance (e.g., a TV). Various other types of electronic devices are also available.

The wireless power transmission device 100 may wirelessly transmit the power 10 to the plurality of electronic devices 150-1, 150-2, . . . , 150-n. For example, the wireless power transmission device 100 may transmit power to the plurality of electronic devices 150-1, 150-2, . . . , 150-n in the resonance scheme. When the wireless power transmission device 100 adopts the resonance scheme, a distance at which power may be transmitted and received between the wireless power transmission device 100 and the plurality of electronic devices 150-1, 150-2, . . . , 150-n may be 1 m or less, preferably 30 cm or less. In addition, for example, the wireless power transmission device 100 may transmit power to the plurality of electronic devices 150-1, 150-2, . . . , 150-n in the induction scheme. When the wireless power transmission device 100 adopts the induction scheme, a distance at which power may be transmitted and received between the wireless power transmission device 100 and the plurality of electronic devices 150-1, 150-2, . . . , 150-n may be preferably 10 cm or less. According to a certain embodiment, at least one of the plurality of electronic devices 150-1, 150-2, . . . , 150-n may receive power from the wireless power transmission device 100 in the resonance scheme, and at least another one of the plurality of electronic devices 150-1, 150-2, . . . , 150-n may receive power from the wireless power transmission device 100 in the induction scheme.

A processor included in the wireless power transmission device 100 may control to wirelessly transmit preset power 10 to the plurality of electronic devices 150-1, 150-2, . . . , 150-n. For example, the preset power for the plurality of electronic devices 150-1, 150-2, . . . , 150-n may be power having a magnitude set to drive (e.g., wake up) processors included in the plurality of electronic devices 150-1, 150-2, . . . , 150-n. The preset power 10 may be set in consideration of various pieces of information about the plurality of electronic devices 150-1, 150-2, . . . , 150-n (e.g., various types of the electronic devices 150-1, 150-2, . . . , 150-n, information about various required powers of the plurality of electronic devices 150-1, 150-2, . . . , 150-n, information about voltages or currents related to various powers of the plurality of electronic devices 150-1, 150-2, . . . , 150n, information about various ratings (e.g., effective values) of the plurality of electronic devices 150-1, 150-2, . . . , 150n, and orientation information (e.g., posture information) about the plurality of electronic devices 150-1, 150-2, . . . , 150-n). The magnitude of the power 10 transmitted to the plurality of electronic devices 150-1, 150-2, . . . , 150-n may be the same or different for each of the plurality of electronic devices 150-1, 150-2, . . . , 150-n.

The wireless power transmission device 100 may perform communication with the plurality of electronic devices 150-1, 150-2, . . . , 150n, simultaneously, sequentially, selectively, or independently. Each of the plurality of electronic devices 150-1, 150-2, . . . , 150-n may transmit and receive data to and from the wireless power transmission device 100 in one of the in-band and out-of-band schemes.

The data may be data for controlling power reception at each of the plurality of electronic devices. Further, the data may include various pieces of information about the plurality of electronic devices 150-1, 150-2, . . . , 150-n.

FIG. 2 is a perspective view illustrating a wireless power transmission device and at least one electronic device according to an embodiment of the disclosure.

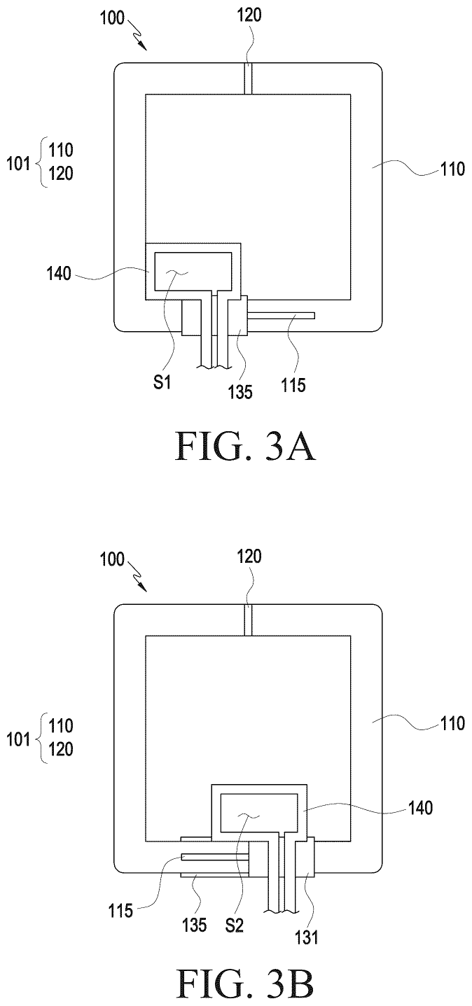

FIGS. 3A and 3B are plan views illustrating a wireless power transmission device according to various embodiments of the disclosure.

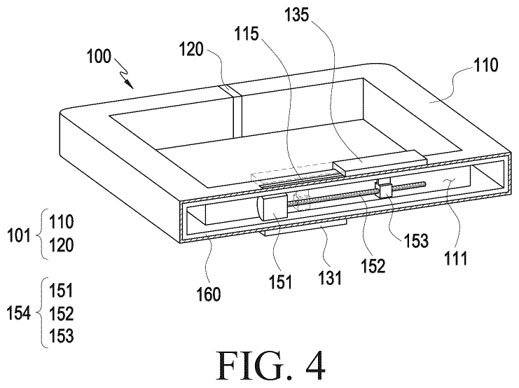

The embodiments of FIGS. 2, 3A, and 3B may be combined with the embodiment of FIG. 1 or the embodiments of FIGS. 4, 5A, 5B, 6A to 6C, 7A, 7B, 8A, 8B, 9A to 9C, 10A to 10C, 11, 12A, 12B, 13A, and 13B.

Referring to FIG. 2, the wireless power transmission device 100 (e.g., the wireless power transmission device 100 of FIG. 1) may include the resonator 101 (e.g., the resonator 101 of FIG. 1) and an automatic matching module (magnetic bodies 131 and 135).

According to an embodiment, the resonator 101 may include at least one coil 110 (e.g., the coil 110 of FIG. 1) and at least one capacitor 120 (e.g., the capacitor 120 of FIG. 1). According to an embodiment, the at least one coil 110 may be formed in, but is not limited to, a loop-like or ring-like shape. For example, the at least one coil 110 may include at least one inductor.

According to an embodiment, the at least one coil 110 may have at least one portion in a shape cut off or spaced apart from an adjacent portion. According to an embodiment, the at least one capacitor 120 may be disposed in the cut or spaced portion.

According to an embodiment, the at least one coil 110 may include an internal space (e.g., an internal space 111 of FIG. 4) formed inside the at least one coil 110.

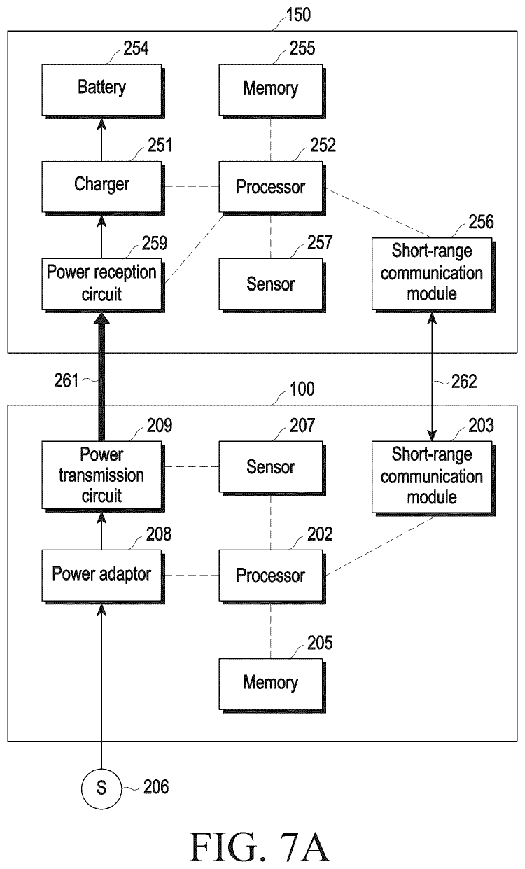

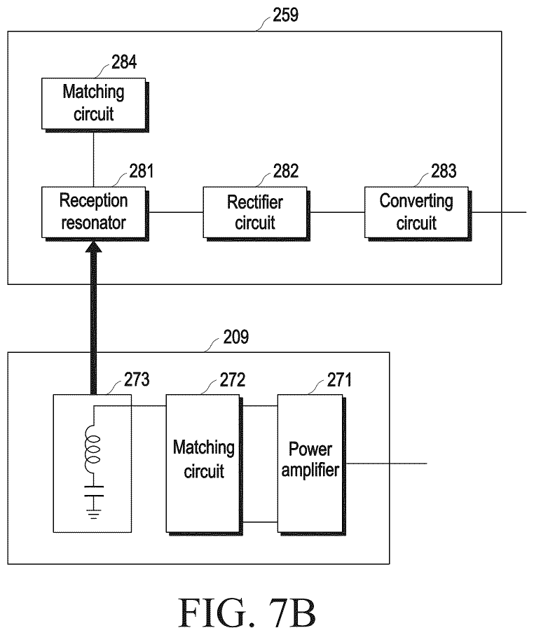

According to an embodiment, various electronic components (e.g., a processor 202, a short-range communication module 203, or memory 205 of FIG. 7A) may be accommodated in the internal space 111.

According to an embodiment, a power transmission circuit (e.g., a power transmission circuit 209 of FIG. 7A) may be disposed in the internal space 111.

According to an embodiment, when current is applied to the at least one coil 110, the current may flow only on a surface (e.g., outer surface) of the at least one coil 110 due to a skin effect. According to an embodiment, since no current flows inside or on an inner surface of the at least one coil 110, a magnetic flux may be canceled in the internal space 111.

According to an embodiment, the wireless power transmission device 100 may adopt the resonance scheme as a power transmission scheme for the electronic device 150 located in the vicinity. According to an embodiment, the wireless power transmission device 100 may perform a power output or transmission function for the electronic device 150 by using the resonator 101.

According to an embodiment, the power transmission circuit (e.g., the power transmission circuit 209 of FIG. 7A) of the wireless power transmission device 100 may output the power 10 in the form of an electromagnetic field to the electronic device 150 through the at least one coil 110. In an embodiment, the electronic device 150 may receive the power 10 in the form of an electromagnetic field through a reception resonator (e.g., a reception resonator 281 of FIG. 7B) of a power reception circuit (e.g., a power reception circuit 259 of FIG. 7A), and charge a battery (e.g., a battery 254 of FIG. 7A).

According to an embodiment, the wireless power transmission device 100 may further include the automatic matching module (magnetic bodies 131 and 135).

According to an embodiment, the automatic matching module (magnetic bodies 131 and 135) may include a fixed magnetic body 131 and a movable magnetic body 135.

According to an embodiment, the fixed magnetic body 131 may be disposed on the at least one coil 110. According to an embodiment, the fixed magnetic body 131 may be disposed to cover at least a portion of the at least one coil 110.

According to an embodiment, the fixed magnetic body 131 may be formed of, but is not limited to, ferrite.

According to an embodiment, at least a portion of the fixed magnetic body 131 may be fixed to the at least one coil 110. Accordingly, the fixed magnetic body 131 may have a fixed position with respect to the at least one coil 110.

According to an embodiment, the movable magnetic body 135 may be slidably coupled to the at least one coil 110. According to an embodiment, the movable magnetic body 135 may be disposed to cover at least a portion of the at least one coil 110.

According to an embodiment, the movable magnetic body 135 may be formed of, but is not limited to, ferrite.

According to an embodiment, the movable magnetic body 135 may slide along a slot 115 formed on the at least one coil 110. For example, the slot 115 may extend in a first direction substantially the same as a direction in which current flows through the at least one coil 110. For example, the first direction may be an extension direction of a portion of the at least one coil 110, to which the fixed magnetic body 131 is coupled. For example, the movable magnetic body 135 may slide along the first direction.

According to an embodiment, the slot 115 may be formed on at least a portion of a top or bottom surface of the at least one coil 110.

According to an embodiment, the movable magnetic body 135 may slide along the slot 115 in the first direction based on a force provided from a movement module (e.g., a movement module 154 of FIG. 4) described below.

According to an embodiment, the wireless power transmission device 100 may further include a feeding coil (e.g., a feeding coil 140 of FIGS. 3A and 3B).

Referring to FIGS. 3A and 3B, the feeding coil 140 may be fixed to at least a portion of the movable magnetic body 135. Further, when the movable magnetic body 135 slides, the feeding coil 140 may slide together with the movable magnetic body 135.

According to an embodiment, the feeding coil 140 may have at least a portion formed in a loop or ring shape. In an embodiment, the feeding coil 140 may be formed to cause an induced electromotive force in the at least one coil 110. In an embodiment, the feeding coil 140 and the at least one coil 110 may be formed to be mutually induced. The feeding coil 140 may further include a feeding port (not shown) to which external power (or an external power voltage) is applied.

According to an embodiment, the feeding coil 140 may also be referred to as a feeding loop or a feeding structure. According to an embodiment, the feeding coil 140 may be an inductor formed of, but not limited to, a copper material.

According to an embodiment, as the feeding coil 140 and the movable magnetic body 135 may slide, the resonant frequency of the resonator 101 may be changed (or controlled).

Referring to FIGS. 2, 3A, and 3B, the wireless power transmission device 100 according to an embodiment may be configured to adjust the matching efficiency of the power transmission circuit (e.g., the power transmission circuit 209 of FIG. 7A) and the resonator 101.

For example, when the electronic device 150 approaches the wireless power transmission device 100, the inductance of the resonator 101 of the wireless power transmission device 100 may change due to the electronic device 150 and a metal component of the electronic device 150. Accordingly, the resonance frequency of the resonator 101 may change, and the transmission efficiency of the power 10 to the electronic device 150 may decrease.

Further, when the distance between the wireless power transmission device 100 and the electronic device 150 changes, coupling coefficients of the wireless power transmission device 100 and the electronic device 150 may change depending on the transmission distance of the power 10, which may change the input impedance of the resonator 101. Accordingly, the transmission efficiency or resonance efficiency may decrease depending on matching loss of the power transmission circuit (e.g., the power transmission circuit 209 of FIG. 7A) and the resonator 101 of the wireless power transmission device 100.

According to an embodiment, the wireless power transmission device 100 may adjust the input impedance of the resonator 101 through the automatic matching module (magnetic bodies 131 and 135) and the feeding coil 140.

According to an embodiment, when the movable magnetic body 135 slides relative to the fixed magnetic body 131, the imaginary value of the input impedance of the resonator 101 may be adjusted. For example, the position of the movable magnetic body 135 relative to the fixed magnetic body 131 may be changed, and accordingly, the imaginary value of the input impedance of the resonator 101 may be adjusted. Further, when the feeding coil 140 slides together with the movable magnetic body 135, the absolute value of the input impedance of the resonator 101 may be adjusted. For example, when the feeding coil 140 slides, the positions of areas S1 and S2 where an inner area of the feeding coil 140 and an inner area of the at least one coil 110 overlap each other may be changed, and thus, an induced electromotive force caused in the at least one coil 110 may be adjusted. Accordingly, the absolute value of the input impedance of the resonator 101 may be adjusted.

According to an embodiment, the wireless power transmission device 100 may slide the movable magnetic body 135 and the feeding coil 140 so that the matching efficiency for transmission of the power 10 is improved according to the distance between the wireless power transmission device 100 and the electronic device 150.

FIG. 4 is a perspective view illustrating a wireless power transmission device according to an embodiment of the disclosure.

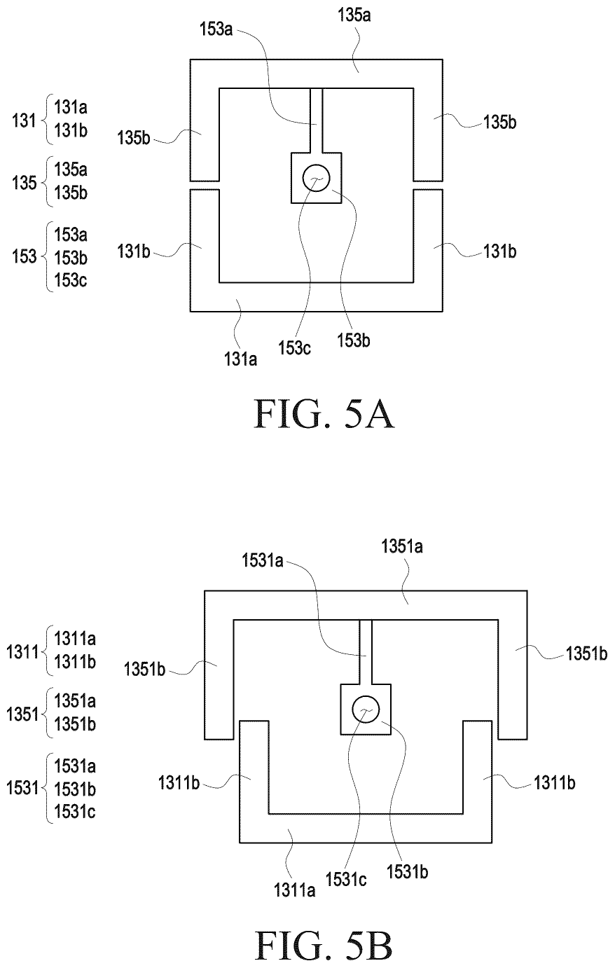

The embodiment of FIG. 4 may be combined with the embodiments of FIGS. 1, 2, 3A, and 3B or the embodiments of FIGS. 5A, 5B, 6A to 6C, 7A, 7B, 8A, 8B, 9A to 9C, 10A to 10C, 11, 12A, 12B, 13A, and 13B.

Referring to FIG. 4, the wireless power transmission device 100 (e.g., the wireless power transmission device 100 of FIGS. 1, 2, 3A, and 3B) may further include a support member 160 and the movement module 154.

According to an embodiment, the support member 160 may be formed of a non-metallic material (e.g., a polymer) and disposed in the internal space 111 of the at least one coil 110.

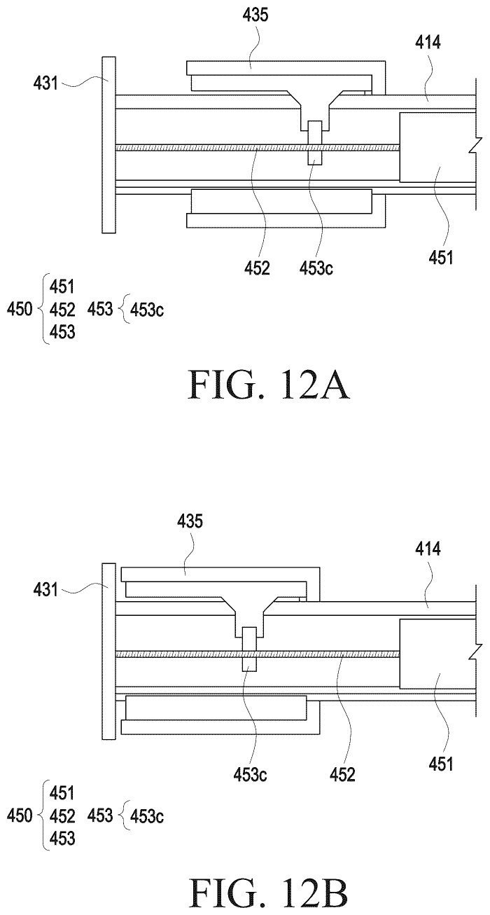

According to an embodiment, the support member 160 may be coupled to an inner circumferential surface of the at least one coil 110 (e.g., the coil 110 of FIGS. 12, 3A, and 3B). Further, the support member 160 may support the at least one coil 110 and protect components arranged inside the at least one coil 110.

According to an embodiment, the movement module 154 may be disposed in the internal space 111 of the at least one coil 110. According to an embodiment, the movement module 154 may include a motor 151, a rotation rod 152, and a movable connector 153.

According to an embodiment, the motor 151 may provide a driving force for sliding the movable magnetic body 135. According to an embodiment, the motor 151 may rotate the rotation rod 152 connected to the motor 151 in one direction or in the other direction opposite to the one direction.

According to an embodiment, the rotation rod 152 may be connected to the motor 151 and configured to be rotated by the motor 151. According to an embodiment, the rotation rod 152 may have screw threads or screw grooves formed on an outer circumferential surface thereof.

According to an embodiment, the movable connector 153 may be slidably connected to the rotation rod 152. Further, the movable connector 153 may be coupled to the movable magnetic body 135. For example, at least a portion of the movable connector 153 may be coupled to the movable magnetic body 135, while penetrating the slot 115.

Further, the movable connector 153 may include screw threads or screw grooves corresponding to the screw threads of the rotation rod 152, or a movable hole formed with screw threads (e.g., a movable hole 153c of FIGS. 5A and 5B). According to an embodiment, as the movable connector 153 has the movable hole connected to the rotation rod 152, the movable connector 153 may slide according to rotation of the rotation rod 152. Accordingly, the movable magnetic body 135 connected to the movable connector 153 may also slide. For example, the rotation rod 152 and the movable hole (e.g., the movable hole 153c of FIGS. 5A and 5B) may be screw-coupled.

FIG. 5A is a cross-sectional view illustrating an automatic matching module according to an embodiment of the disclosure.

The embodiment of FIG. 5A may be combined with the embodiments of FIGS. 1, 2, 3A, 3B, and 4 or the embodiments of FIGS. 5B, 6A to 6C, 7A, 7B, 8A, 8B, 9A to 9C, 10A to 10C, 11, 12A, 12B, 13A, and 13B.

According to an embodiment, the fixed magnetic body 131 (e.g., the fixed magnetic body 131 of FIGS. 2, 3A, 3B, and 4) may include a first fixed portion 131a and a pair of second fixed portions 131b extending in the same direction from both ends of the first fixed portion 131a. For example, the pair of second fixed portions 131b may extend toward the movable magnetic body 135.

According to an embodiment, the movable magnetic body 135 (e.g., the movable magnetic body 135 of FIGS. 2, 3A, 3B, and 4) may include a first movable portion 135a and a pair of second movable portions 135b extending in the same direction from both ends of the first movable portion 135a. For example, the pair of second movable portions 135b may extend toward the fixed magnetic body 131.

According to an embodiment, when the fixed magnetic body 131 and the movable magnetic body 135 are disposed to correspond to each other, they may form a closed structure covering an overall portion of the at least one coil 110.

According to an embodiment, the movable connector 153 (e.g., the movable connector 153 of FIG. 4) may include a first connector portion 153a coupled to the first movable portion 135a of the movable magnetic body 135, and a second connector portion 153b formed at one end of the first connector portion 153a and coupled to the rotation rod 152. Further, the movable connector 153 may further include the movable hole 153c which is formed on the second connector portion 153b and into which the rotation rod 152 is inserted.

According to an embodiment, the first movable portion 135a may be disposed on one surface (e.g., the top surface) of the at least one coil 110, and the first fixed portion 131a may be disposed on the other surface (e.g., the bottom surface) facing in the opposite direction to the one surface of the at least one coil 110.

FIG. 5B is a cross-sectional view illustrating an automatic matching module according to an embodiment of the disclosure.

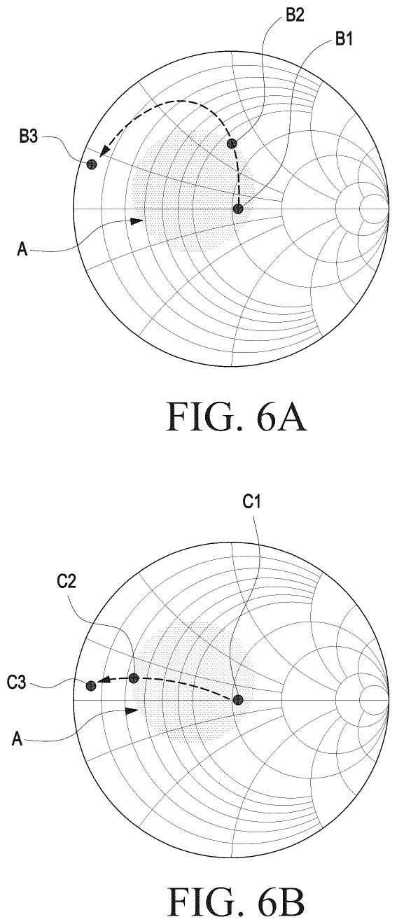

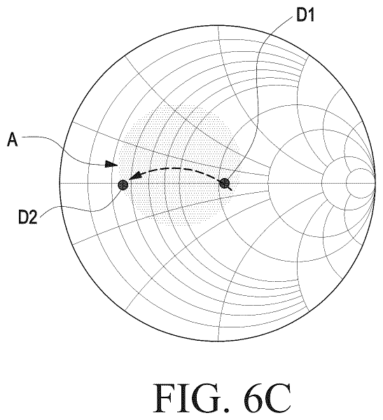

The embodiment of FIG. 5B may be combined with the embodiments of FIGS. 1, 2, 3A, 3B, 4, and 5A or the embodiments of FIGS. 6A to 6C, 7A, 7B, 8A, 8B, 9A to 9C, 10A to 10C, 11, 12A, 12B, 13A, and 13B.

According to an embodiment, a fixed magnetic body 1311 (e.g., the fixed magnetic body 131 of FIGS. 2, 3A, 3B, and 4) may include a first fixed portion 1311a and a pair of second fixed portions 1311b extending in the same direction from both ends of the first fixed portion 1311a. For example, the pair of second fixed portions 1311b may extend toward a movable magnetic body 1351.

According to an embodiment, the movable magnetic body 1351 (e.g., the movable magnetic body 135 of FIGS. 2, 3A, 3B, and 4) may include a first movable portion 1351a and a pair of second movable portions 1351b extending in the same direction from both ends of the first movable portion 1351a. For example, the pair of second movable portions 1351b may extend toward the fixed magnetic body 1311.

According to an embodiment, the pair of second movable portions 1351b may be disposed to cover at least a portion of a side surface (e.g., an outer side surface) of the pair of second fixed portions 1311b. According to an embodiment, when the fixed magnetic body 1311 and the movable magnetic body 1351 are disposed to correspond to each other, they may form a closed structure covering at least an overall portion of the at least one coil 110.

According to an embodiment, a movable connector 1531 (e.g., the movable connector 153 of FIG. 4) may include a first connector portion 1531a coupled to the first movable portion 1351a of the movable magnetic body 1351, and a second connector portion 1531b formed at one end of the first connector portion 1531a and coupled to the rotation rod 152. In addition, the movable connector 1351 may further include a movable hole 1531c which is formed on the second connector portion 1531b and into which the rotation rod 152 is inserted.

According to an embodiment, the first movable portion 1351a may be disposed on one surface (e.g., the top surface) of the at least one coil 110, and the first fixed portion 1311a may be disposed on the other surface (e.g., the bottom surface) facing in the opposite direction to the one surface of the at least one coil 110.

FIG. 6A is a Smith chart illustrating input impedances of a resonator according to distances between a wireless power transmission device and an electronic device according to an embodiment of the disclosure.

FIG. 6B is a Smith chart illustrating input impedances of a resonator according to distances between a wireless power transmission device and an electronic device according to an embodiment of the disclosure.

FIG. 6C is a Smith chart illustrating input impedances of a resonator according to distances between a wireless power transmission device and an electronic device according to an embodiment of the disclosure.

Referring to FIGS. 6A to 6C, a high-efficiency region A represents a region of an input impedance with high efficiency of power transmission to the electronic device 150.

The comparative example of FIG. 6A is a Smith chart in the case where the input impedance of the resonator is not tuned when the distance between the wireless power transmission device and the electronic device is changed.

Referring to FIG. 6A, when the distance between the wireless power transmission device and the electronic device is 10 cm or more, the input impedance of the resonator may be located in the high-efficiency region A (a section from B1 to B2). However, when the distance between the wireless power transmission device and the electronic device is less than 10 cm, the input impedance of the resonator may not be located in the high-efficiency region A (a section from B2 to B3). It may be identified from the section from B2 to B3 that at least one of the imaginary value or absolute value of the input impedance of the resonator is not located in the high-efficiency region A.

The comparative example of FIG. 6B is a Smith chart in which the imaginary value of the input impedance of the resonator is tuned and the absolute value thereof is not tuned, when the distance between the wireless power transmitter and the electronic device is changed.

In the comparative example of FIG. 6B, the imaginary value of the input impedance of the resonator is adjusted by sliding the movable magnetic body, and the absolute value of the input impedance of the resonator is not adjusted by not sliding the feeding coil.

Referring to FIG. 6B, when the distance between the wireless power transmitter and the electronic device is 2 cm or more, the input impedance of the resonator may be located in the high-efficiency region A (a section from C1 to C2). However, when the distance between the wireless power transmitter and the electronic device is less than 2 cm, the input impedance of the resonator may not be located in the high-efficiency region A (a section from C2 to C3). It may be identified from the section from C2 to C3 that the absolute value of the input impedance of the resonator is not located in the high-efficiency region A.

FIG. 6C is a Smith chart in the case where the imaginary value and the absolute value of the input impedance of the resonator are tuned, when the distance between the wireless power transmission device and the electronic device is changed according to an embodiment of the disclosure.

In the comparative example of FIG. 6C, the imaginary value of the input impedance of the resonator may be adjusted by sliding the movable magnetic body, and the absolute value of the input impedance of the resonator may be adjusted by sliding the feeding coil together with the movable magnetic body.

Referring to FIG. 6C, when the distance between the wireless power transmission device and the electronic device is 0 cm or more, the input impedance of the resonator may be located in the high-efficiency region A (a section from D1 to D2).

FIG. 7A illustrates a wireless power transmission device and an electronic device according to an embodiment of the disclosure. FIG. 7B is a detailed block diagram illustrating a power transmission circuit and a power reception circuit according to an embodiment of the disclosure.

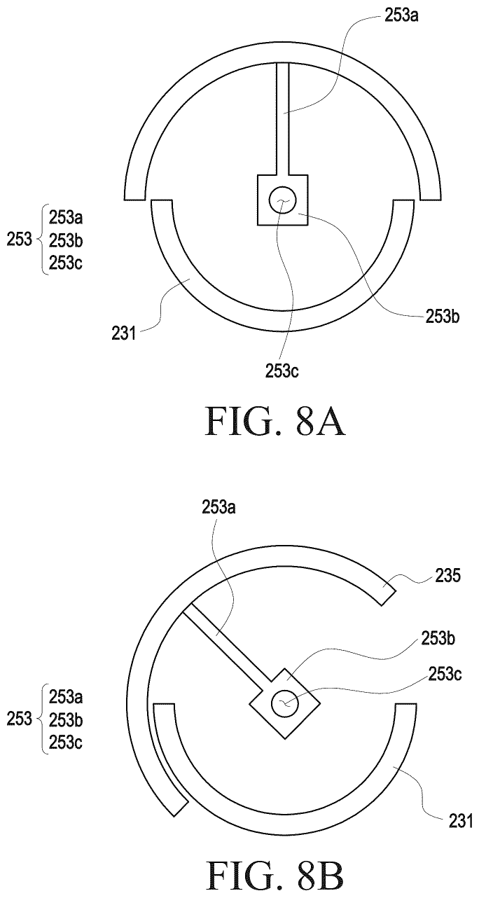

The embodiments of FIGS. 7A and 7B may be combined with the embodiments of FIGS. 1, 2, 3A, 3B, 4, 5A, 5B, and 6A to 6C or the embodiments of FIGS. 8A, 8B, 9A to 9C, 10A to 10C, 12A, 12B, 13A, and 13B.

Referring to FIG. 7A, the wireless power transmission device 100 (e.g., the wireless power transmission device 100 of FIGS. 1, 2, 3A, 3B, and 4) according to an embodiment may include at least one of the processor 202, the short-range communication module 203, the memory 205, a power adapter 208, or the power transmission circuit 209. The electronic device 150 (e.g., the electronic device 150 of FIGS. 1 and 2) according to an embodiment may include at least one of a charger 251, a processor 252, a short-range communication module 256, the battery 254, memory 255, or the power reception circuit 259.

The power transmission circuit 209 according to an embodiment may wirelessly transmit power 261 according to at least one of an induction scheme, a resonance scheme, or an electromagnetic wave scheme. The detailed configurations of the power transmission circuit 209 and the power reception circuit 259 will be described below in more detail with reference to FIG. 7B. The processor 202 may control the overall operation of the wireless power transmission device 100. For example, the processor 202 may determine whether to transmit the power 261, control the magnitude of the power 261, or control at least one function (e.g., start or stop of charging) of the electronic device 150. The processor 202 or the processor 252 may be implemented as various circuits capable of performing computations, including a general-purpose processor such as a CPU, a microprocessor, a micro controlling unit (MCU), a field programmable gate array (FPGA), and so on, and its type is not limited. The processor 202 may transmit and receive data 262 to and from the electronic device 150 through the short-range communication module 203. The data may be used to control wireless power transmission and reception. The short-range communication module 203 and the short-range communication module 256 may be implemented as, for example, an out-of-band short-range communication module (e.g., a Bluetooth (BT or BLE) communication module or an NFC communication module) or as an in-band load modulation communication module. In the case of an in-band communication type, the load modulation communication module may include, for example, a switch connected to the coil of the power reception circuit 259 directly or through another element, and a dummy load (e.g., a dummy resistor or a dummy capacitor) connected to the coil directly via the switch or through another element. The load modulation communication module may identify information based on a change in a voltage or current applied to the coil in the power transmission circuit 209, which is detected during switch on/off. The power adapter 208 may receive power from a power source 206 and provide it to the power transmission circuit 209. The power adapter 208 may be, for example, a power interface, and may not be included in the wireless power transmission device 100 depending on implementation of various embodiments.

The power reception circuit 259 according to an embodiment may wirelessly receive power from the power transmission circuit 209 according to at least one of an induction scheme, a resonance scheme, or an electromagnetic wave scheme. The power reception circuit 259 may perform power processing such as rectifying received AC waveform power into a DC waveform, converting a voltage, or regulating power. The charger 251 may charge the battery 254 with the received regulated power (e.g., DC power). The charger 251 may adjust at least one of the voltage or current of the received power and transmit it to the battery 254. The battery 254 may store the power and transmit it to other hardware. Although not shown, a power management integrated circuit (PMIC) (not shown) may receive power from the power reception circuit 259 and transmit it to other hardware, or may receive power from the battery 254 and transmit it to other hardware. In addition, the charger 251 may be included in the PMIC.

The processor 252 may control the overall operation of the electronic device 150. The memory 255 may store instructions for performing the overall operation of the electronic device 150. The memory 205 may store instructions for performing the overall operation of the wireless power transmission device 100, or may store a lookup table for the relationship between information obtained through the short-range communication module 203 and the magnitude of power to be transmitted or equation information for the relationship between the obtained information and the magnitude of power to be transmitted. The memory 205 or the memory 255 may be implemented in various forms such as read only memory (ROM), random access memory (RAM), or flash memory, and the implementation form of the memory 205 or 255 is not limited.

Referring to FIG. 7B, the power transmission circuit 209 may include a power amplifier 271, a matching circuit 272 (or a matching network), and a transmission resonant circuit 273. The power amplifier 271 or an inverter circuit may convert DC power received from the power adapter 208 into AC power. The frequency of the AC power may be set to, but is not limited to, 100 kHz to 205 kHz or 6.78 MHz according to a standard. The matching circuit 272 may change at least one of the capacitance or reactance of a circuit connected to the transmission resonant circuit 273 under the control of the processor 202, thereby impedance-matching the power transmission circuit 209 and the power reception circuit 259 to each other. The transmission resonant circuit 273 may include at least one coil and at least one capacitor. When AC power (or current) is applied to the transmission resonant circuit 273, a magnetic field with a magnitude changing over time may be formed from the transmission resonant circuit 273, and thus power in the form of an electromagnetic field may be output or transmitted to the power reception circuit 259 of the electronic device 150. An induced electromotive force may be generated in the reception resonator 281 of the power reception circuit 259 by a magnetic field with a magnitude changing over time formed around it, and thus the power reception circuit 259 may receive power wirelessly. The reception resonator 281 may include at least one coil and at least one capacitor, although not shown in the drawing. A rectifier circuit 282 may rectify the power of a received AC waveform. A converting circuit 283 may adjust the voltage of the rectified power and transmit it to the PMIC or the charger. The power reception circuit 259 may further include a regulator, or the converting circuit 283 may be replaced with a regulator. A matching circuit 284 may change at least one of the capacitance or reactance of a circuit connected to the reception resonator 281 under the control of the processor 252, thereby impedance-matching the power transmission circuit 209 and the power reception circuit 259 to each other.

Referring again to FIG. 7A, the wireless power transmission device 100 according to an embodiment of the disclosure may include at least one sensor 207.

The at least one sensor 207 may be a sensor that measures the voltage and current of the wireless power transmission device 100. The wireless power transmission device 100 may measure the output impedance of the power amplifier 271 described below and/or the input impedance of the transmission resonant circuit 273 (e.g., the impedance of a signal input from the matching circuit 272 to the transmission resonant circuit 273) through the at least one sensor 207. For example, power consumption may be monitored by measuring a transmission voltage VTX_IN and a transmission current ITX_IN using the sensor 207, and thus, a change in the input impedance of the transmission resonant circuit 273 may be detected. When the impedance change is detected, whether the electronic device 150 receiving wireless power has been mounted/removed, whether a foreign substance has been detected, and a change in the magnitude of received power may be identified. For example, when one of the plurality of electronic devices 150 moves and the distance from the wireless power transmission device 100 and the electronic device 150 becomes smaller during charging of the electronic devices 150 in the wireless power transmission device 100, the reception power and efficiency of the other electronic devices may decrease. The processor 202 may control the transmission and efficiency of wireless power to the plurality of electronic devices 150 according to a predetermined algorithm or a command input from a user, considering a detected impedance change.

The electronic device 150 according to an embodiment of the disclosure may include at least one sensor 257.

For example, the electronic device 150 may autonomously detect movement of the electronic device 150 through the at least one sensor 257 (e.g., a motion sensor). The motion sensor for detecting movement may include, but is not limited to, for example, at least one of a gyro sensor, an acceleration sensor, an angular velocity sensor, a gravity sensor, a geomagnetic sensor, or an infrared sensor. For example, the electronic device 150 may measure a voltage VRECT output from the rectifier circuit 282 using the at least one sensor 257. Based on the measured output voltage VRECT, a change in the positional relationship between the electronic device 150 and the wireless power transmission device 100 (whether it is closer to or farther from the resonator) may be identified. Data sensed through the sensor 257 may be provided to the processor 252, and the data received by the processor 252 may be provided to the wireless power transmission device 100 through the short-range communication module 256.

FIGS. 8A and 8B are cross-sectional views illustrating an automatic matching module according to various embodiments of the disclosure.

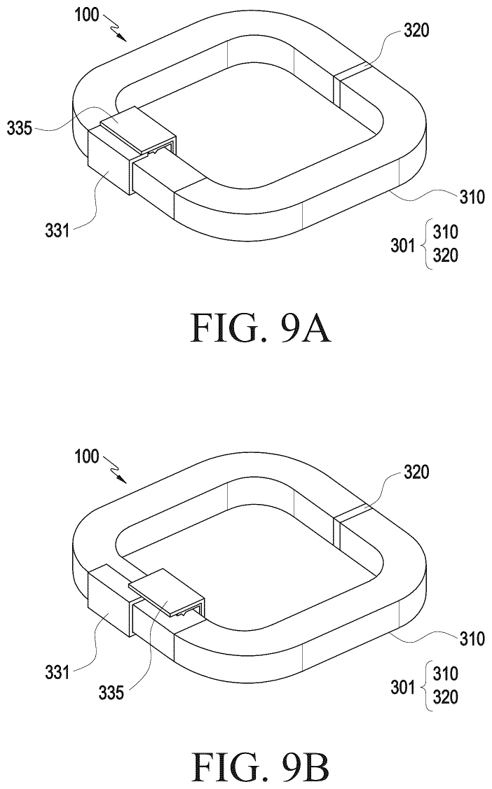

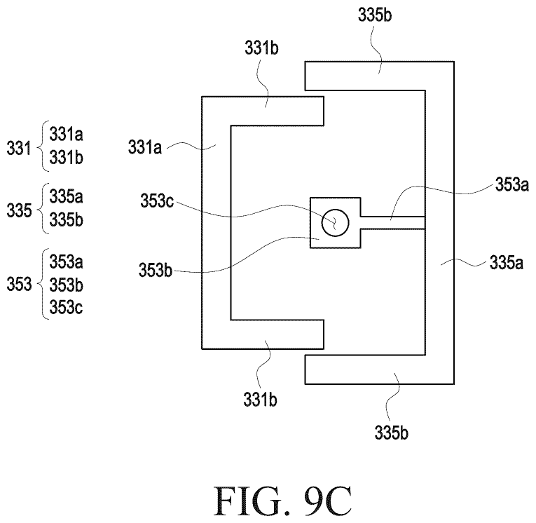

The embodiments of FIGS. 8A to 8B may be combined with the embodiments of FIGS. 1, 2, 3A, 3B, 4, 5A, 5B, 6A to 6C, 7A, and 7B or the embodiments of FIGS. 9A to 9C, 10A to 10C, 11, 12A, 12B, 13A, and 13B.

Referring to FIGS. 8A and 8B, a fixed magnetic body 231 (e.g., the fixed magnetic body 131 of FIGS. 2, 3A, 3B, and 4) may be formed in a semicircular shape. Further, a movable magnetic body 235 (e.g., the movable magnetic body 135 of FIGS. 2, 3A, 3B, and 4) may be formed in a semicircular shape. The radius of curvature of the movable magnetic body 235 may be greater than the radius of curvature of the fixed magnetic body 231. For example, the fixed magnetic body 231 and the movable magnetic body 235 may have a cross-sectional shape of a semicircle.

According to an embodiment, a movable connector 253 (e.g., the movable connector 153 of FIG. 4) may include a first connector portion 253a, a second connector portion 253b, and a rotation hole 253c.

According to an embodiment, the rotation hole 253c may be fixed to the rotation rod 152 (e.g., the rotation rod 152 of FIG. 4). Accordingly, when the rotation rod 152 is rotated by the motor 151 (e.g., the motor 151 of FIG. 4), the movable connector 253 fixed to the rotation rod 152 may be rotated together. The movable magnetic body 235 may change its position relative to the fixed magnetic body 231 by being rotated by the movable connector 253. For example, the movable magnetic body 235 may be disposed to be rotatable relative to the at least one coil 110 (e.g., the at least one coil 110 of FIGS. 1, 2, 3A, 3B, and 4).

According to an embodiment, the movable magnetic body 235 may cover at least a portion of an outer side surface of the fixed magnetic body 231 by being rotated with respect to the at least one coil 110.

According to an embodiment, when the position of the movable magnetic body 235 relative to the fixed magnetic body 231 changes, the imaginary value of the input impedance of the resonator 101 may be adjusted.

FIGS. 9A and 9B are perspective views illustrating a wireless power transmission device according to various embodiments of the disclosure. FIG. 9C is a cross-sectional view illustrating an automatic matching module according to an embodiment of the disclosure.

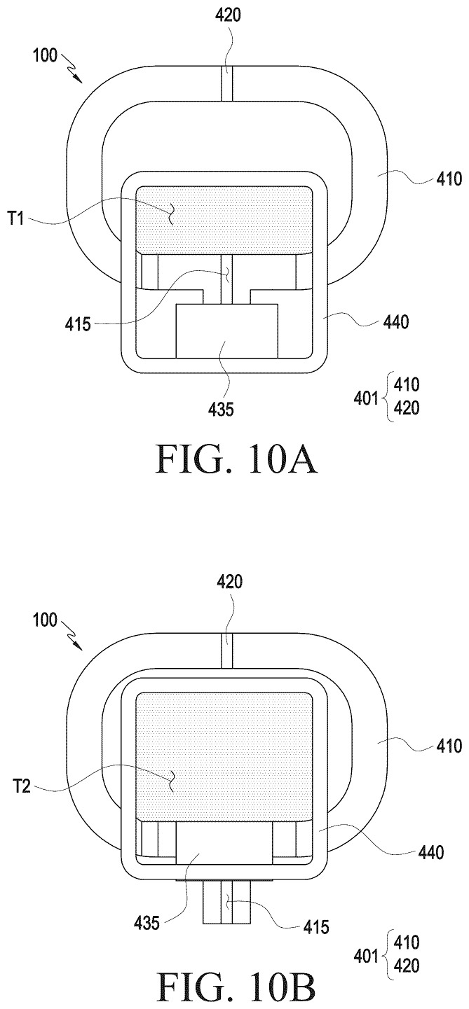

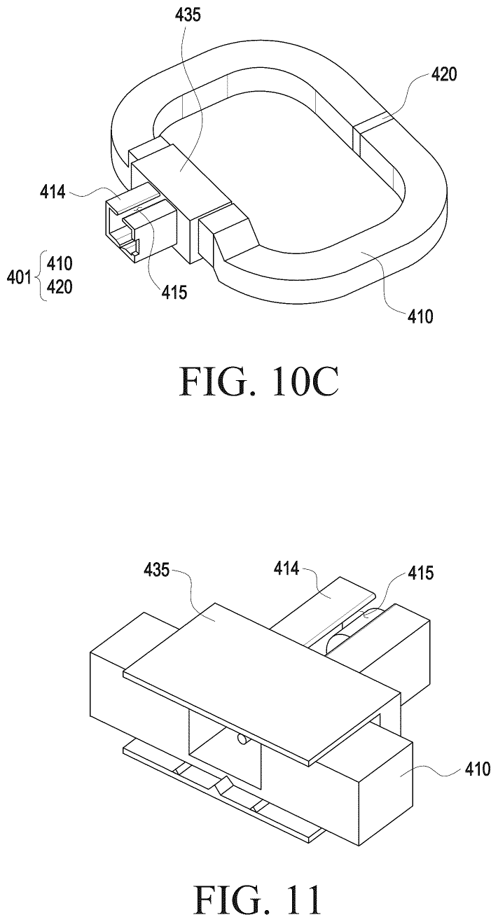

The embodiments of FIGS. 9A to 9C may be combined with the embodiments of FIGS. 1, 2, 3A, 3B, 4, 5A, 5B, 6A to 6C, 7A, 7B, 8A, and 8B or the embodiments of FIGS. 10A to 10C, 11, 12A, 12B, 13A, and 13B.

Referring to FIGS. 9A to 9C, the wireless power transmission device 100 (e.g., the wireless power transmission device 100 of FIGS. 1, 2, 3A, 3B, and 4) may include a resonator 301 (e.g., the resonator 101 of FIGS. 1, 2, 3A, 3B, and 4) including at least one coil 310 (e.g., the at least one coil 110 of FIGS. 1, 2, 3A, 3B, and 4) and at least one capacitor 320 (e.g., the at least one capacitor 120 of FIGS. 1, 2, 3A, 3B, and 4), a fixed magnetic body 331 (e.g., the fixed magnetic body 131 of FIGS. 2, 3A, 3B, and 4), a movable magnetic body 335 (e.g., the movable magnetic body 135 of FIGS. 2, 3A, 3B, and 4), and a movable connector 353 (e.g., the movable connector 153 of FIG. 4).

According to an embodiment, the movable magnetic body 335 may change its position relative to the fixed magnetic body 131 by sliding along a slot (not shown) formed on the at least one coil 310. Accordingly, the imaginary value of the input impedance of the resonator 301 may be adjusted.

According to an embodiment, the fixed magnetic body 331 may include a first fixed portion 331a and a pair of second fixed portions 331b extending in the same direction from both ends of the first fixed portion 331a. For example, the pair of second fixed portions 331b may extend toward the movable magnetic body 351.

According to an embodiment, the movable magnetic body 351 may include a second movable portion 351a and a pair of second movable portions 335b extending in the same direction from both ends of the second movable portion 335b. For example, the pair of second movable portions 335b may extend toward the fixed magnetic body 331.

According to an embodiment, the pair of second movable portions 351b may be disposed to cover at least a portion of a side surface (e.g., an outer side surface of the pair of second fixed portions 331b). According to an embodiment, when the fixed magnetic body 331 and the movable magnetic body 351 are disposed to correspond to each other, they may form a closed structure that covers an overall portion of the at least one coil 110.

According to an embodiment, the movable connector 353 may include a first connector portion 353a coupled to the first movable portion 335a of the movable magnetic body 351, and a second connector portion 353b formed at one end of the first connector portion 353a and coupled to the rotation rod 152. In addition, the movable connector 353 may further include a movable hole 353c which is formed on the second connector portion 353b and into which the rotation rod 152 is inserted.

According to an embodiment, the first movable portion 335a may be disposed on an inner side surface (e.g., a surface facing the inside of the loop) of the at least one coil 310. In addition, the slot (not shown) formed on the at least one coil 310 may be formed on the inner side surface of the at least one coil 310, so that the first connector portion 353a may be disposed in the slot.

According to an embodiment, the first movable portion 335a may be disposed on one surface of the at least one coil 310 (e.g., the inner side surface facing the inside of the loop shape formed by the at least one coil 310), and the first fixed portion 331a may be disposed on the other surface facing in the opposite direction of the one surface of the at least one coil 310 (e.g., an outer side surface facing the outside of the loop shape formed by the at least one coil 310).

FIGS. 10A and 10B are plan views illustrating a wireless power transmission device according to various embodiments of the disclosure. FIG. 10C is a perspective view illustrating a wireless power transmission device according to an embodiment of the disclosure. FIG. 11 is a perspective view illustrating at least one coil and a movable magnetic body according to an embodiment of the disclosure. FIGS. 12A and 12B are cross-sectional views illustrating an automatic matching module according to various embodiments of the disclosure.

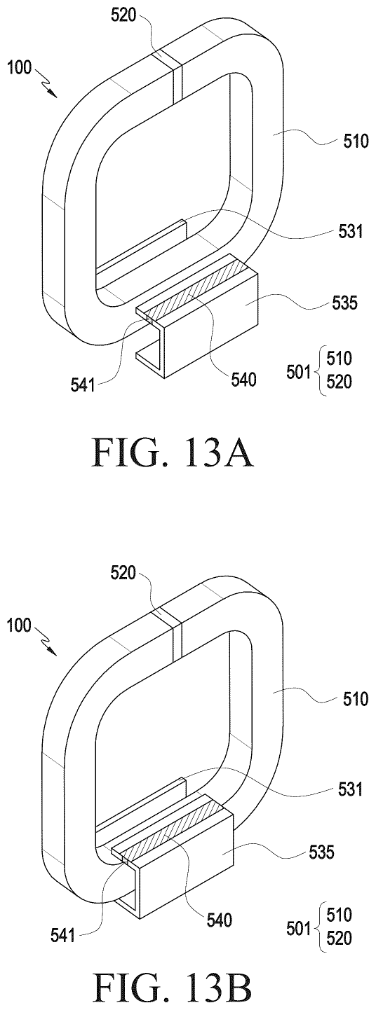

The embodiments of FIGS. 10A to 10C, 11, 12A, and 12B may be combined with the embodiments of FIGS. 1, 2, 3A, 3B, 4, 5A, 5B, 6A to 6C, 7A, 7B, 8A, 8B, 9A, and 9B or the embodiments of FIGS. 13A and 13B.

Referring to FIGS. 10A to 10C, 11, 12A, and 12B, the wireless power transmission device 100 (e.g., the wireless power transmission device 100 of FIGS. 1, 2, 3A, 3B, and 4) may include a resonator 401 (e.g., the resonator 101 of FIGS. 1, 2, 3A, 3B, and 4) including at least one coil 410 (e.g., the coil 110 of FIGS. 1 to 4) and at least one capacitor 420 (e.g., the capacitor 420 of FIGS. 1, 2, 3A, 3B, and 4), a fixed magnetic body 431 (e.g., the fixed magnetic body 131 of FIGS. 1, 2, 3A, 3B, and 4), a movable magnetic body 435 (e.g., the movable magnetic body 135 of FIGS. 1, 2, 3A, 3B, and 4), and a movement module 450 (e.g., the movement module 154 of FIG. 4).

According to an embodiment, the wireless power transmission device 100 may further include a bracket portion 414 extending from the at least one coil 410. According to an embodiment, the bracket portion 414 may be defined as a portion of the at least one coil 410.

According to an embodiment, the bracket portion 414 may extend from at least a portion of a side surface (e.g., an outer side surface) of the at least one coil 410 toward the outside of the at least one coil 410. According to an embodiment, the bracket portion 414 may extend in a first direction perpendicular to a direction in which current flows through the at least one coil 410. The first direction may be defined as a direction from the inside of a loop shape formed by the at least one coil 410 toward the outside, or the opposite direction.

According to an embodiment, a slot 415 may be formed on the bracket portion 414 along the first direction.

Accordingly, the movable magnetic body 435 may slide along the first direction. For example, the movable magnetic body 435 may slide toward the inside of the loop shape formed by the at least one coil 410 or toward the outside of the loop shape.

According to an embodiment, when the movable magnetic body 435 slides relative to the fixed magnetic body 431, the imaginary value of the input impedance of the resonator 401 may be adjusted. For example, the position of the movable magnetic body 435 relative to the fixed magnetic body 431 may be changed, and accordingly, the imaginary value of the input impedance of the resonator 101 may be adjusted. In addition, when a feeding coil 440 slides together with the movable magnetic body 435, the absolute value of the input impedance of the resonator 401 may be adjusted. For example, when the feeding coil 440 slides, the positions and sizes of areas T1 and T2 where an inner area of the feeding coil 440 overlaps an inner area of the at least one coil 410 may be changed, so that an induced electromotive force caused in the at least one coil 410 may be adjusted. Accordingly, the absolute value of the input impedance of the resonator 401 may be adjusted.

According to an embodiment, the fixed magnetic body 431 may be disposed on an inner side surface of at least one coil 410, facing the inside of the loop shape.

According to an embodiment, the movement module 450 may be disposed in an internal space of the bracket portion 414. According to an embodiment, the movement module 450 may include a motor 451, a rotation rod 452, and a movable connector 453.

According to an embodiment, the motor 451 may provide a driving force for sliding the movable magnetic body 435. According to an embodiment, the motor 451 may rotate the rotation rod 452 connected to the motor 451 in one direction or in the other direction opposite to the one direction.

According to an embodiment, the rotation rod 452 may be connected to the motor 451 and configured to be rotated by the motor 451. According to an embodiment, the rotation rod 452 may have screw threads or screw grooves formed on its outer circumferential surface.

According to an embodiment, the movable connector 453 may be slidably connected to the rotation rod 452. Further, the movable connector 453 may be coupled to the movable magnetic body 435. For example, at least a portion of the movable connector 453 may be coupled to the movable magnetic body 435, while penetrating the slot 415.

Further, the movable connector 453 may include a movable hole 453c in which screw threads or screw grooves corresponding to the screw threads or screw grooves of the rotation rod 452 are formed. According to an embodiment, as the movable connector 453 has the movable hole connected to the rotation rod 452, it may slide according to rotation of the rotation rod 452. Accordingly, the movable magnetic body 435 connected to the movable connector 453 may also slide.

FIGS. 13A and 13B are perspective views illustrating a wireless power transmission device according to an embodiment of the disclosure.

The embodiments of FIGS. 13A and 13B may be combined with the embodiments of FIGS. 1, 2, 3A, 3B, 4, 5A, 5B, 6A to 6C, 7A, 7B, 8A, 8B, 9A to 9C, 10A to 10C, 11, 12A, and 12B.

Referring to FIGS. 13A and 13B, the wireless power transmission device 100 (e.g., the wireless power transmission device 100 of FIGS. 1, 2, 3A, 3B, and 4) may include a resonator 501 (e.g., the resonator 101 of FIGS. 1, 2, 3A, 3B, and 4) including at least one coil 510 (e.g., the coil 110 of FIGS. 1, 2, 3A, 3B, and 4) and at least one capacitor 520 (e.g., the capacitor 120 of FIGS. 1, 2, 3A, 3B, and 4), a fixed magnetic body 531 (e.g., the fixed magnetic body 131 of FIGS. 1, 2, 3A, 3B, and 4), and a movable magnetic body 535 (e.g., the movable magnetic body 135 of FIGS. 1, 2, 3A, 3B, and 4).

According to an embodiment, the fixed magnetic body 531 may be disposed on one surface (e.g., the top surface or bottom surface) of the at least one coil 510. In addition, the movable magnetic body 535 may be disposed on the other surface (e.g., the bottom surface or top surface) of the at least one coil 510.

According to an embodiment, the movable magnetic body 535 may be configured to slide in a first direction different from a direction in which current flows through the at least one coil 510. For example, the first direction may be a direction substantially perpendicular to an extension direction of a portion of the at least one coil 510, to which the fixed magnetic body 431 is coupled. Further, the first direction may be defined as a direction spaced apart from the top or bottom surface connecting an inner side surface (e.g., a surface facing the inside of a loop shape) and an outer side surface (e.g., a surface facing the outside of the loop shape) of the at least one coil 410. For example, the movable magnetic body 535 may slide toward the fixed magnetic body 531 or away from the fixed magnetic body 531. For example, the movable magnetic body 535 may be disposed on the top surface of the at least one coil 510, and slide toward the fixed magnetic body 531 fixed on the bottom surface of the at least one coil 510 or away from the fixed magnetic body 531.

According to an embodiment, when the movable magnetic body 535 slides relative to the fixed magnetic body 531, the imaginary value of the input impedance of the resonator 501 may be adjusted. For example, the movable magnetic body 535 may change its position relative to the fixed magnetic body 531, and accordingly, the imaginary value of the input impedance of the resonator 501 may be adjusted.

According to an embodiment, a feeding coil 540 (e.g., the feeding coil 140 of FIGS. 3A and 3B) may be disposed on at least a portion of the movable magnetic body 535. The feeding coil 540 may be disposed on at least a portion of a surface of the movable magnetic body 535.

According to an embodiment, the feeding coil 540 may be fixed to at least a portion of the movable magnetic body 535. Further, when the movable magnetic body 535 slides, the feeding coil 540 may slide together with the movable magnetic body 535.

According to an embodiment, the feeding coil 540 may further include a feeding port 541 to which external power (or an external power voltage) is applied. According to an embodiment, the feeding coil 540 may be formed to cause an induced electromotive force in the at least one coil 510. According to an embodiment, the feeding coil 540 and the at least one coil 510 may be formed to be mutually induced.

According to an embodiment, the feeding coil 540 may be referred to as a feeding loop or a feeding structure. According to an embodiment, the feeding coil 540 may be, but is not limited to, an inductor formed of a copper material.

According to an embodiment, the resonant frequency of the resonator 501 may be changed (or controlled) by sliding the feeding coil 540 and the movable magnetic body 535.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., a program) including one or more instructions that are stored in a storage medium (e.g., internal memory or external memory) that is readable by a machine (e.g., the electronic device 150). For example, a processor (e.g., the processor 252) of the machine (e.g., the electronic device 150) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

A wireless power transmission device for spatial wireless charging may include a coil for transmitting power and a power transmission circuit. The coil may be configured to generate a magnetic field to transmit wireless charging power for charging an electronic device located around the wireless power transmission device.

As the electronic device approaches the wireless power transmission device, a resonator of the wireless power transmission device may experience a change in inductance due to a metal component of the electronic device that requires charging. Accordingly, there is a risk of matching loss between the power transmission circuit and the coil.

According to one embodiment of the disclosure, a resonator structure which may improve the matching efficiency of a power transmission circuit and at least one coil, and a wireless power transmission device including the same may be provided.

However, the problems to be solved in the disclosure are not limited to the problem mentioned above, and may be determined in various ways without departing from the spirit and scope of the disclosure.

According to an embodiment of the disclosure, a wireless power transmission device including a resonator structure may improve power transmission efficiency for an electronic device by adjusting the input impedance of at least one coil of the wireless power transmission device according to the distance of the electronic device.

The effects that may be obtained from the disclosure are not limited to the effects mentioned above, and other effects that are not mentioned may be clearly understood by those skilled in the art from the following description.

According to an embodiment of the disclosure, the wireless power transmission device 100 may include the resonator 101, the fixed magnetic body 131, the movable magnetic body 135, the feeding coil 140, or the movement module 154. The resonator 101 may include the at least one coil 110 or the at least one capacitor 120. The fixed magnetic body 131 may be coupled to the at least one coil. The movable magnetic body 135 may be disposed to be slidable in a first direction on the at least one coil. The feeding coil 140 may be at least partially coupled to the movable magnetic body. The feeding coil 140 may be configured to slide together with the movable magnetic body. The movement module 154 may be disposed at the at least one coil. The movement module 154 may be configured to provide a driving force for sliding the movable magnetic body in the first direction.

According to an embodiment, the at least one coil may include the slot 115 formed on at least a portion of the at least one coil. The movable magnetic body may be configured to slide along the slot.

According to an embodiment, the slot may be formed on at least one of a top surface or a bottom surface of the at least one coil.

According to an embodiment, the slot may be formed on an inner side surface of the at least one coil.

According to an embodiment, the movement module may include the motor 151, the rotation rod 152, or the movable connector 153. The motor 151 may be configured to provide a driving force for sliding the movable magnetic body. The rotation rod 152 may be connected to the motor and rotate in one direction or in another direction opposite to the one direction. The movable connector 153 may be fastened on the rotation rod. The movable connector 153 may be at least partially coupled to the movable magnetic body. The movable connector 153 may be configured to slide along a longitudinal direction of the rotation rod based on rotation of the rotation rod.

According to an embodiment, the movable connector may include the first connector portion 153a, the second connector portion 153b, and the movable hole 153c. The first connector portion 153a may be coupled to at least a portion of the movable magnetic body. The second connector portion 153b may be coupled to one end of the first connector portion. The second connector portion 153b may be fastened on the rotation rod. The movable hole 153c may be formed to penetrate at least a portion of the second connector portion. The rotation rod may be inserted into the movable hole 153c.

According to an embodiment, the rotation rod and the movable hole may be screw-coupled to each other.

According to an embodiment, the fixed magnetic body may include the first fixed portion 131a or the pair of second fixed portions 131b. The pair of second fixed portions 131b may extend from both ends of the first fixed portion toward the movable magnetic body. The movable magnetic body may include the first movable portion 135a or the pair of second movable portions 135b. The first movable portion 135a may face the first fixed portion. The pair of second movable portions 135b may extend from both ends of the first movable portion toward the fixed magnetic body.

According to an embodiment, the pair of second movable portions 1351b may be configured to cover at least a portion of an outer side surface of the pair of second fixed portions 1311b.

According to an embodiment, the first movable portion may be disposed on one surface of the at least one coil. The first fixed portion may be disposed on another surface facing in an opposite direction to the one surface of the at least one coil.

According to an embodiment, the one surface of the at least one coil may be an inner side surface facing an inside of a loop shape formed by the at least one coil.

According to an embodiment, the one surface of the at least one coil may be at least one of a top surface or a bottom surface of the loop shape formed by the at least one coil.

According to an embodiment, when the feeding coil slides, at least one of a position or a size of an area where the at least one coil and the feeding coil overlap may be changed.

According to an embodiment, the first direction may be a direction substantially the same as a direction in which current flows in the at least one coil.

According to an embodiment, the first direction may be a direction different from the direction in which current flows in the at least one coil.

According to an embodiment of the disclosure, the wireless power transmission device 100 may include the resonator 101, the fixed magnetic body 131, the movable magnetic body 135, the feeding coil 140, or the movement module 154. The resonator 101 may include the at least one coil 110 or the at least one capacitor 120. The fixed magnetic body 131 may be coupled to the at least one coil. The movable magnetic body 135 may be disposed to be movable on the at least one coil. The feeding coil 140 may be at least partially coupled to the movable magnetic body. The feeding coil 140 may be configured to move together with the movable magnetic body. The movement module 154 may be disposed in the at least one coil. The movement module 154 may be configured to provide a driving force for moving the movable magnetic body.

According to an embodiment, the movable magnetic body 235 may be disposed to be rotatable relative to the at least one coil.

According to an embodiment, the movable magnetic body 235 may be configured to at least partially cover at least a portion of an outer side surface of the fixed magnetic body 231.

According to an embodiment, the fixed magnetic body and the movable magnetic body may have a cross-sectional shape of a semicircle.

According to an embodiment, the movable magnetic body may be configured to slide in a direction approaching the fixed magnetic body or in a direction away from the fixed magnetic body.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wireless power transmission device, comprising:
a resonator including at least one coil and at least one capacitor;
a fixed magnetic body coupled to the at least one coil;
a movable magnetic body disposed to be slidable in a first direction on the at least one coil;
a feeding coil at least partially coupled to the movable magnetic body and configured to slide together with the movable magnetic body; and
a movement module disposed at the at least one coil and configured to provide a driving force for sliding the movable magnetic body in the first direction.

2. The wireless power transmission device of claim 1,
wherein the at least one coil includes a slot formed on at least a portion of the at least one coil, and
wherein the movable magnetic body is configured to slide along the slot.

3. The wireless power transmission device of claim 2, wherein the slot is formed on at least one of a top surface or a bottom surface of the at least one coil.

4. The wireless power transmission device of claim 2, wherein the slot is formed on an inner side surface of the at least one coil.

5. The wireless power transmission device of claim 1, wherein the movement module includes:
a motor configured to provide a driving force for sliding the movable magnetic body;
a rotation rod connected to the motor and configured to rotate in one direction or in another direction opposite to the one direction; and
a movable connector fastened on the rotation rod, at least partially coupled to the movable magnetic body, and configured to slide along a longitudinal direction of the rotation rod based on rotation of the rotation rod.

6. The wireless power transmission device of claim 5, wherein the movable connector includes:
a first connector portion coupled to at least a portion of the movable magnetic body;
a second connector portion coupled to one end of the first connector portion and fastened on the rotation rod; and
a movable hole formed to penetrate at least a portion of the second connector portion, and in which the rotation rod is inserted.

7. The wireless power transmission device of claim 6, wherein the rotation rod and the movable hole are screw-coupled to each other.

8. The wireless power transmission device of claim 1,
wherein the fixed magnetic body includes:
a first fixed portion, and
a pair of second fixed portions extending from both ends of the first fixed portion toward the movable magnetic body, and
wherein the movable magnetic body includes:
a first movable portion facing the first fixed portion, and
a pair of second movable portions extending from both ends of the first movable portion toward the fixed magnetic body.

9. The wireless power transmission device of claim 8, wherein the pair of second movable portions are configured to cover at least a portion of an outer side surface of the pair of second fixed portions.

10. The wireless power transmission device of claim 8,
wherein the first movable portion is disposed on one surface of the at least one coil, and
wherein the first fixed portion is disposed on another surface facing in an opposite direction to the one surface of the at least one coil.

11. The wireless power transmission device of claim 10, wherein the one surface of the at least one coil is an inner side surface facing an inside of a loop shape formed by the at least one coil.

12. The wireless power transmission device of claim 11, wherein the one surface of the at least one coil is at least one of a top surface or a bottom surface of the loop shape formed by the at least one coil.

13. The wireless power transmission device of claim 1, wherein when the feeding coil slides, at least one of a position or a size of an area where the at least one coil and the feeding coil overlap is changed.

14. The wireless power transmission device of claim 1, wherein the first direction is a direction substantially a same as a direction in which current flows in the at least one coil.

15. The wireless power transmission device of claim 1, wherein the first direction is a direction different from the direction in which current flows in the at least one coil.

16. The wireless power transmission device of claim 2, wherein the movement module includes:
a motor configured to provide a driving force for sliding the movable magnetic body;
a rotation rod connected to the motor and configured to rotate in one direction or in another direction opposite to the one direction; and
a movable connector fastened on the rotation rod, at least partially coupled to the movable magnetic body, and configured to slide along a longitudinal direction of the rotation rod based on rotation of the rotation rod.

17. The wireless power transmission device of claim 16, wherein the movable connector includes:
a first connector portion coupled to at least a portion of the movable magnetic body;
a second connector portion coupled to one end of the first connector portion and fastened on the rotation rod; and
a movable hole formed to penetrate at least a portion of the second connector portion, and in which the rotation rod is inserted.

18. The wireless power transmission device of claim 17, wherein the rotation rod and the movable hole are screw-coupled to each other.

19. The wireless power transmission device of claim 2,
wherein the fixed magnetic body includes:
a first fixed portion, and
a pair of second fixed portions extending from both ends of the first fixed portion toward the movable magnetic body, and
wherein the movable magnetic body includes:
a first movable portion facing the first fixed portion, and
a pair of second movable portions extending from both ends of the first movable portion toward the fixed magnetic body.

20. The wireless power transmission device of claim 19, wherein the pair of second movable portions are configured to cover at least a portion of an outer side surface of the pair of second fixed portions.
